(19) United States
(12) Patent Application Publication
(10) Pub. No.: US 2012/0219760 A1
(43) Pub. Date: Aug. 30, 2012

(54) APPARATUS AND METHOD FOR PROVIDING ISOLATION BETWEEN COMPONENTS IN MICROFABRICATED DEVICES

(75) Inventors: James F. Detry, Plymouth, MN (US); Robert J. Carlson, Brooklyn Park, MN (US); Pamela Marie Norris, Charlottesville, VA (US); Arthur Weston Lichtenberger, Charlottesville, VA (US); Roy Matthews, Cedar Park, TX (US); Casey Marie Nabors Bauer, Charlottesville, VA (US); Matthew Linton Bauer, Charlottesville, VA (US)

(73) Assignee: HONEYWELL INTERNATIONAL INC., Morristown, NJ (US)

(21) Appl. No.: 13/036,922

(22) Filed: Feb. 28, 2011

(51) Int. Cl. B32B 3/26; F16F 15/00; H05K 7/00

(52) U.S. Cl. 428/158; 428/304.4; 428/319.1; 428/316.6; 361/679.01; 181/207

(57) ABSTRACT

An apparatus and method for providing isolation between components in microfabricated devices is provided. In one embodiment, a microfabricated device comprises: a base layer; a microfabricated component; and a non-sacrificial aerogel layer in contact with the microfabricated component and supporting the microfabricated thermal component on the base layer. The non-sacrificial aerogel layer is positioned to provide at least one of thermal, electrical or acoustic isolation between the microfabricated thermal component and the base layer.

### GOVERNMENT INTEREST STATEMENT

This invention was made with Government support under GG11092-130718 awarded by DARPA. The Government may have certain rights in the invention.

### BACKGROUND

Often, to achieve proper operation of a microfabricated device, portions of the device may need to be isolated from other portions of the device. For example, a thermal component may need to be thermally isolated from certain other components within the device to minimize unwanted heat transfer. However, because such devices are extremely small, the physical space available for utilization to provide such isolation is very limited. Components requiring such isolation are frequently fragile. Further, there are steps in fabrication processes that often subject such fragile components to potential damaging forces. For example, the process of sawing a wafer into separate devices can cause vibrations cause an isolated component to vibrate and break. Materials such as polymers are sometimes introduced in the fabrication provide support and dampen vibrations. However, even though such materials may prevent the isolated component from breaking during the device fabrication process, the subsequent removal of those materials can itself cause damage to the isolated component.

For the reasons stated above and for other reasons stated below which will become apparent to those skilled in the art upon reading and understanding the specification, there is a need in the art for an apparatus and method for providing isolation between components in microfabricated devices.

### SUMMARY

The Embodiments of the present invention provide methods and systems for providing isolation between components in microfabricated devices and will be understood by reading and studying the following specification.

In one embodiment, a microfabricated device comprises: a base layer; a microfabricated thermal component; and a non-sacrificial aerogel layer in contact with the microfabricated thermal component and supporting the microfabricated thermal component on the base layer, wherein the non-sacrificial aerogel layer is positioned to provide thermal isolation between the microfabricated thermal component and the base layer.

In another embodiment, a microfabricated device comprises: a base layer; a microfabricated electrical component; and a non-sacrificial aerogel layer in contact with the microfabricated electrical component and supporting the microfabricated electrical component on the base layer, wherein the non-sacrificial aerogel layer is positioned to provide electrical isolation between the microfabricated electrical component and the base layer.

In yet another embodiment, a microfabricated device comprises: a substrate layer; a microfabricated component; and a non-sacrificial aerogel layer in contact with the microfabricated component and structurally supporting the microfabricated component on the substrate layer such that the non-sacrificial aerogel layer dampens movement of the microfabricated component caused by acoustic vibrations.

### BRIEF DESCRIPTION OF DRAWINGS

Embodiments of the present invention can be more easily understood and further advantages and uses thereof more readily apparent, when considered in view of the description of the preferred embodiments and the following figures in which:

FIG. 1 is a diagram illustrating a device of one embodiment of the present invention utilizing an aerogel layer to provide component isolation;

FIG. 2 is a diagram illustrating a device of one embodiment of the present invention utilizing an aerogel layer to provide component isolation;

FIG. 3 is a diagram illustrating a device of one embodiment of the present invention utilizing an aerogel layer to provide component isolation;

FIG. 4 is a diagram illustrating a device of one embodiment of the present invention utilizing an aerogel layer to provide component isolation; and

FIG. 5 is a flow chart illustrating a method of one embodiment of the present invention.

In accordance with common practice, the various described features are not drawn to scale but are drawn to emphasize specific features relevant to the exemplary embodiments.

### DETAILED DESCRIPTION

In the following detailed description, references are made to the accompanying drawings that form a part hereof, and in which is shown by way of illustration specific illustrative embodiments. However, it is to be understood that other embodiments may be utilized and that logical, mechanical, and electrical changes may be made. Furthermore, the method presented in the drawing figures and the specification is not to be construed as limiting the order in which the individual acts may be performed. The following detailed description is, therefore, not to be taken in a limiting sense.

Embodiments of the present invention utilize silica aerogel for forming isolation layers during fabrication of microelectromechanical systems (MEMS). The aerogel isolation layers are non-sacrificial, meaning that the aerogel layers are not removed during fabrication, but remain in the finished device. Aerogels are highly porous solids produced by a sol-gel process in which the liquid component of a gel has been replaced with a gas. Aerogels have extremely low densities yet provide a structurally robust foundation that can support other layers in a MEMS device. Further, aerogels cure into a web of filaments forming a porous, sponge-like structure that, per unit volume, is comprised mostly of voids. This porous structure allows aerogels to function well as thermal and electrical isolators as the structure limits heat transfer and electrical conductivity throughout the aerogel. Due to their rigidity and ability to insulate, aerogels are also suitable for structurally supporting isolated portions of electrical devices during microfabrication and during normal operation. Because the structure provides for dampening of vibrations and other forces, is also useful for providing isolation layers for acoustic isolation of components within the device.

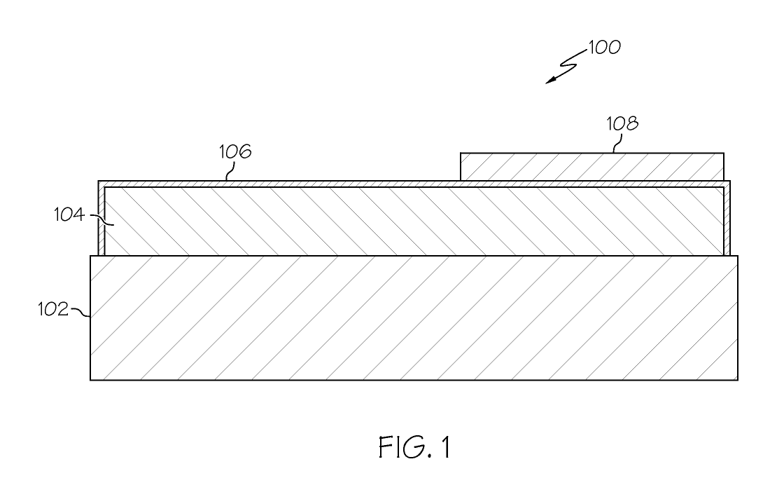

FIG. 1 is a diagram illustrating a device 100 (such as a MEMS device) of one embodiment of the present invention that uses aerogel materials to thermally isolate a fabricated device. Device 100 includes substrate layer 102. Substrate layer 102 is a base layer for creating different electromechanical devices and provides support to electromechanical devices formed thereon. Substrate layer 102 can be formed from silicon or other materials used in microfabrication. Device 100 also includes an aerogel layer 104. Aerogel layer 104 is a layer of aerogel that has been deposited on a surface of substrate layer 102. In one embodiment, Aerogel layer 104 is made from an aerogel composed of silica. As would be appreciated by one of ordinary skill in the art upon reading this specification, for other embodiments, an aerogel layer formed from other materials may be selected. Such selection of alternate materials is within the skill of one of ordinary skill in the art and would be based on the particular type of isolation (for example, thermal, electrical, acoustic) they are attempting to achieve. In some implementations, the aerogel is applied to the surface of substrate layer 102 through spin coating until the aerogel layer achieves a desired thickness. For example, the aerogel layer is applied to substrate layer 102 such that the thickness of aerogel layer 104 is ten microns. In some implementations, substrates can be treated to promote strengthened bonding between substrate and aerogel. Aerogel is an effective thermal insulator and, therefore, aerogel layer 104 thermally isolates substrate layer 102 from structures supported by aerogel layer 104. Further, aerogel layer 104 is made from either hydrophobic or hydrophilic aerogel.

As would be appreciated by one of ordinary skill in the art upon reading this specification, hydrophilic aerogel structurally deteriorates when exposed to liquids. Thus, manufacturing of device 100 should either be limited to dry processes to avoid damage to aerogel layer 104, or aerogel layer 104 should otherwise be protected from contact with liquids. In the embodiment shown in FIG. 1, a protective layer 106 surrounds aerogel layer 104 and prevents aerogel layer 104 from coming into contact with a liquid. Protective layer 106 may be an external coating such as a hydrophobic aerogel, SiO₂, quartz, or other material impervious to liquids. Protective layer 106 need only be applied in a sufficient thickness to prevent intrusion of the liquid. Typically, aerogel layer 104 will have a greater thickness than protective layer 106. For example, in one embodiment where aerogel layer 104 itself has a thickness of 10 microns, a protective layer 106 of 0.1-0.2 microns has been shown to be sufficient. In the embodiment shown in FIG. 1, protective layer 106 encapsulates the otherwise exposed surfaces of aerogel layer 104. Protective layer 106 protects the top and side surfaces of aerogel layer 104 from liquids, while substrate layer 102 protects the bottom surface of aerogel layer 104. With aerogel layer 104 protected, its ability to further support microfabricated structures built on top of it will not be compromised by contact with solvents used in the fabrication process or contact with liquids.

Further, once in place, protective layer 106 provides a smooth surface that can be utilized to deposit heaters, wires, or other devices. Frequently, aerogel layer 104 has a rough surface that prevents the mounting of small components on the surface of aerogel layer 104. Protective layer 106, being made of a material with a smoother surface, allows the mounting of smaller components above the aerogel layer. In an alternative implementation, aerogel layer 104 is constructed in such a way that it has a smoother surface.

Device 100 also includes a component 108 formed on top of the aerogel layer 104. For the purpose of providing an example, component 108 is referred to herein as a thermal component that needs to be thermally and physically isolated from substrate layer 102 for proper operation. For example, in one embodiment, component 108 is a thin film heater. In such an embodiment, if the thin film heater should come into contact with substrate layer 102, then at least a portion of the heat generated by the thin film heater will be lost to substrate layer 102. In the embodiment shown in FIG. 1, the aerogel isolation layer 104 functions not only to provide a structural support on which component 108 can be formed, but also thermally isolates component 108 from substrate layer 102, preventing thermal transfer between component 108 and substrate layer 102. That is, because the thin film heater rests on aerogel layer 104, aerogel layer 104 will limit heat transfer between the thin film heater and substrate layer 102.

In other embodiments, component 108 may be a component requiring electrical or acoustic isolation in which case an aerogel isolation layer 104 would be applied appropriately to provide that form of isolation. In one alternate embodiment, component 108 is an electrical component requiring electrical isolation from a substrate. For example, the electrical component may be a spiral inductor, which would incur coupling losses if not electrically isolated from substrate layer 102. Such losses can cause the inductor to have a low quality factor. Further, there can be capacitive coupling to the conducting substrate layer 102 and signal leakage to other components, each of which may also be mitigated by the isolation provided by aerogel layer 104.

In certain applications, components built on top of an aerogel layer will need to electrically connect to other MEMS components built upon the same substrate. Because the aerogel layer can be relatively thick, connections between the component on top of the aerogel layer and the other MEMS components may experience degraded performance due to the need to form a relatively long connection stepping from the other MEMS components up to the component supported by the aerogel layer. Further, connections are often formed using wire leads that are bonded to MEMS components by pressing the wire leads into a pad. When a wire lead is pressed into a pad on a MEMS component that is supported by an aerogel layer, the resultant pressure can cause the aerogel layer to crack and shatter, degrading both its ability to isolate components from substrate layer 102 and the ability to structurally support those components.

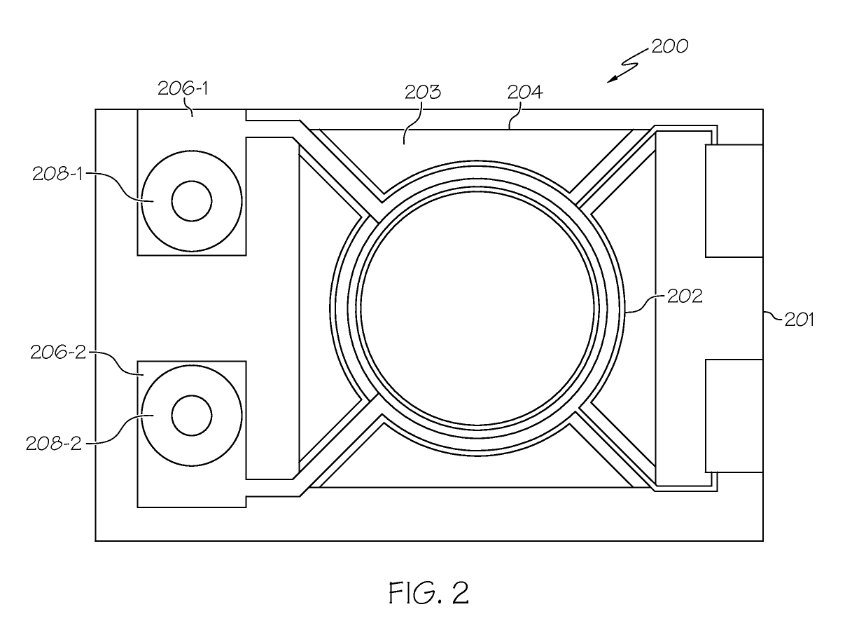

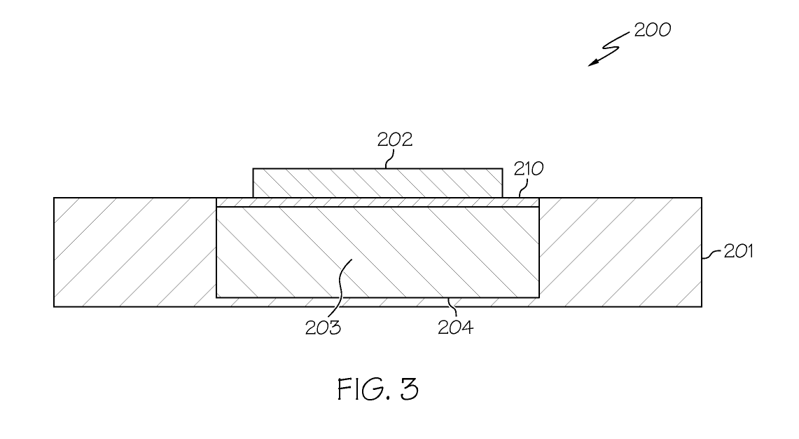

To avoid such problems, in one or more embodiments of the present invention, cavities are formed within the substrate layer of the device at the locations where isolated components are positioned. The cavities can then be filled with aerogel to support a component which needs to be thermally isolated from the substrate. Since the aerogel is deposited in a cavity within the substrate, rather than as a layer over the substrate, components formed on the aerogel will be approximately coplanar with components formed directly on the substrate itself, requiring relatively shorter electrical connections between these components. Also, with aerogel material deposited only within the cavity, components not needing isolation can be formed directly on the substrate layer so that wires and other electromechanical components can be installed without applying pressure to the aerogel that supports the components. FIGS. 2 and 3 provide examples of such a configuration.

FIGS. 2 and 3 are diagrams illustrating a device 200 of one embodiment of the present invention. Device 200 comprises a cavity 204 formed within a substrate 201. The cavity 204 is filled with an aerogel material 203 that supports component 202 as well as providing an isolation layer between component 202 and substrate 201. As would be appreciated by one of ordinary skill in the art upon reading this specification, cavity 204 can be readily formed through etching or other fabrication processes. FIG. 2 is a top view while FIG. 3 is a cut-away view of device 200.

As with the aerogel isolation layer 104 discussed above, aerogel material 203 provides an isolation layer within device 200 for isolating component 202 from substrate 201. As discussed above, the isolation provided may be thermal, electrical, or acoustic, or a combination thereof. Depositing the aerogel material 203 in cavity 204 provides a configuration for utilizing aerogel for isolation and support, without adding to the profile of substrate 201 or the total volume of device 200.

As also shown in FIG. 2, device 200 includes pads 206-1 and 206-2 formed on substrate 201 where wire bonds 208-1 and 208-2 are attached to device 200. In one embodiment, wire bonds 208-1 and 208-2 are attached to pads 206-1 and 206-2 by pressing wire bonds 208-1 and 208-2 into pads 206-1 and 206-2. Pads 206-1 and 206-2 are formed directly above substrate 201 (that is, without an intervening aerogel layer). Thus when pressure is exerted on device 200 to attach wire bonds 208-1 and 208-2 to pads 206-1 and 206-2 no pressure is applied to the aerogel material 203 within cavity 204.

As shown in FIG. 3, in one embodiment, cavity 204 is created within substrate 201 as a rectangular cavity. However, other shapes may be used. In other embodiments, cavity 204 may be cubic, pyramidal, conical, triangular, cylindrical, poly-sided, semi-spherical, or the like. For the embodiment shown in FIG. 3, while cavity 204 encroaches into the surface of substrate 201, the depth of cavity 204 is less than the thickness of substrate 201. FIG. 3 also illustrates a protective layer 210 deposited over aerogel material 203 to prevent structural deterioration due to exposure to solvents or liquids.

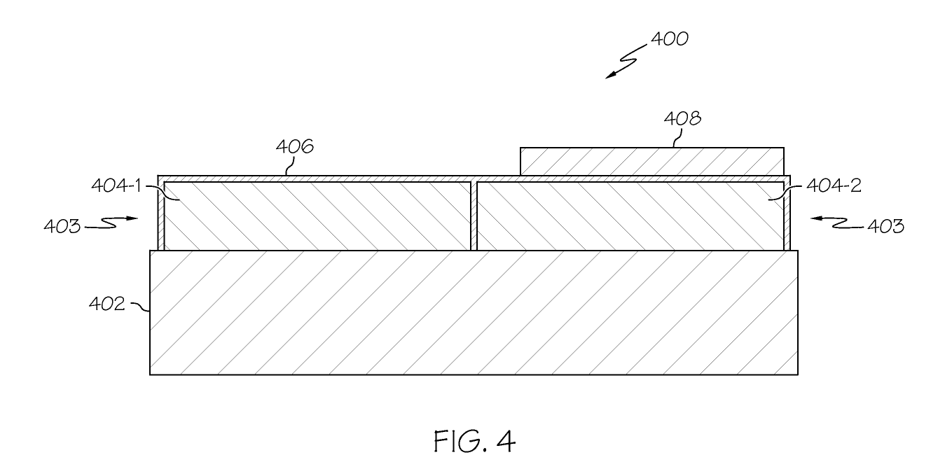

FIG. 4 is a block diagram of another device 400 of an embodiment of the present invention. Device 400 is similar in configuration to device 100 in FIG. 1. In contrast to device 100, device 400 includes an aerogel layer (shown at 403) that has been divided into compartmented aerogel sections 404-1 and 404-2, each encapsulated by protective layer 406. Aerogel sections 404-1 and 404-2 divide aerogel layer 403 into compartments so that, during fabrication, portions of layer 403 can be selectively removed while leaving other portions intact. This may be desirable, for instance, for installing MEMS components onto substrate 402 that perform better when directly supported by substrate layer 402. For example, aerogel section 404-1 can be removed while leaving aerogel section 404-2 to support component 408. A portion of protective layer 406 remains encapsulating aerogel section 404-2, shielding it from exposure to liquid.

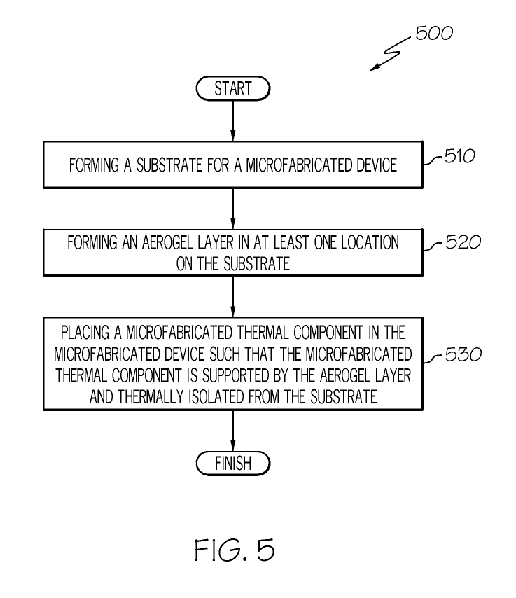

FIG. 5 is a flow diagram illustrating a method 500 of one embodiment of the present invention. The method begins at 510 with forming a substrate for a microfabricated device. For example, the substrate may be a silicon layer or other material used in the fabrication of base layers for microfabricated devices. The method proceeds at 520 with forming an aerogel layer in at least one location on the substrate. As explained above in relation to FIGS. 1-4, in one embodiment, the aerogel layer is formed as a layer on top of the substrate layer. In alternate embodiments, an aerogel layer may comprise a plurality of aerogel compartments which may be selectively removed in sections. In other embodiments, an aerogel layer is formed by depositing aerogel material within a cavity formed in the substrate.

In one embodiment, the method further comprises coating a portion of the aerogel with a protective layer. As explained above in relation to FIGS. 1-4, a protective layer is applied to the aerogel layer to prevent the aerogel layer from coming in to contact with a liquid or solvent. In one or more embodiments, application of the protective layer also provide a smooth surface for mounting electrical components. That is, application of a protective layer decreases the natively high surface roughness of the aerogel, allowing components with dimensions approaching the aerogels surface roughness to be deposited on the protective layer. In certain implementations, the protective layer is made from SiO₂, quartz, nitride isolators, or other protective isolators with low thermal and electrical conductivities. In other embodiments, for example where dry fabrication processes are used, coating the aerogel with a protective layer can be optionally omitted.

The method proceeds at 530 with placing a microfabricated component in the microfabricated device such that the microfabricated component is supported by the aerogel layer and isolated from the substrate. As explained above, for microfabricated components that function more efficiently when thermally or electrically isolated, placing the microfabricated component such that it is supported by an aerogel layer allows components to be both thermally and electrically isolated while being structurally supported.

The descriptions of embodiments above are not intended to limit the scope of embodiments of the present invention only to microfabricated devices that are microelectromechanical system (MEMS) device. Other non-MEMS devices microfabricated devices also benefit from the isolation and support functions provided by embedded aerogel regions as described above. The scope of embodiments of the present invention is intended therefore to cover both MEMS and non-MEMS device.

Although specific embodiments have been illustrated and described herein, it will be appreciated by those of ordinary skill in the art that any arrangement, which is calculated to achieve the same purpose, may be substituted for the specific embodiments shown. Therefore, it is manifestly intended that this invention be limited only by the claims and the equivalents thereof.

What is claimed:

1. A microfabricated device, the device comprising:
a base layer;
a microfabricated thermal component; and
a non-sacrificial aerogel layer in contact with the microfabricated thermal component and supporting the microfabricated thermal component on the base layer, wherein the non-sacrificial aerogel layer is positioned to provide thermal isolation between the microfabricated thermal component and the base layer.

2. The device of claim 1, wherein the non-sacrificial aerogel layer is deposited within a cavity formed in the base layer.

3. The device of claim 1, further comprising a protective layer covering at least one surface of the non-sacrificial aerogel layer.

4. The device of claim 3, wherein the protective layer forms a surface over the non-sacrificial aerogel layer that is smoother than the surface of the non-sacrificial aerogel layer.

5. The device of claim 3, wherein the protective layer is fabricated from a material comprising at least one of SiO₂, hydrophobic aerogel, quartz, or a nitride isolator.

6. The device of claim 1, wherein the microfabricated thermal component comprises a thin film heater.

7. The device of claim 1, wherein the non-sacrificial aerogel layer is formed on top of the base layer.

8. The device of claim 1, wherein the microfabricated thermal component is a device fabricated on top of the non-sacrificial aerogel layer.

9. The device of claim 1, wherein the non-sacrificial aerogel layer comprises a plurality of separate aerogel compartments.

10. A microfabricated device, the device comprising:
a substrate layer;
a microfabricated electrical component; and
a non-sacrificial aerogel layer in contact with the microfabricated electrical component and supporting the microfabricated electrical component on the substrate layer, wherein the non-sacrificial aerogel layer is positioned to provide electrical isolation between the microfabricated electrical component and the substrate layer.

11. The device of claim 10, wherein the microfabricated electrical component is fabricated over a cavity in the base layer, wherein the cavity contains the non-sacrificial aerogel layer.

12. The device of claim 10, further comprising a protective layer that covers surfaces of the non-sacrificial aerogel layer that are not in contact with the substrate layer.

13. The device of claim 12, wherein the protective layer is fabricated from a material comprising at least one of SiO₂, hydrophobic aerogel, quartz, or a nitride isolator.

14. The device of claim 10, wherein the microfabricated electrical component comprises an inductor.

15. The device of claim 10, wherein the microfabricated electrical component is a device fabricated on top of the non-sacrificial aerogel layer.

16. The device of claim 10, wherein the non-sacrificial aerogel layer is further positioned to provide electrical isolation between the microfabricated electrical component and at least one other microfabricated component supported by the substrate layer.

17. A microfabricated device, the device comprising:
a substrate layer;
a microfabricated component; and
a non-sacrificial aerogel layer in contact with the microfabricated component and structurally supporting the microfabricated component on the substrate layer such that the non-sacrificial aerogel layer dampens movement of the microfabricated component caused by acoustic vibrations.

18. The device of claim 17, wherein the microfabricated thermal component is fabricated over a cavity in the base layer, wherein the cavity contains the non-sacrificial aerogel layer.

19. The device of claim 17, further comprising a protective layer covering at least one surface of the non-sacrificial aerogel layer.

20. The device of claim 19, wherein the protective layer forms a surface over the non-sacrificial aerogel layer that is smoother than the surface of the non-sacrificial aerogel layer.
